(19) United States
(12) Patent Application Publication
(10) Pub. No.: US 2024/0365464 A1
(43) Pub. Date: Oct. 31, 2024

(54) CIRCUIT BOARD, ELECTRONIC DEVICE, AND METHOD OF MANUFACTURING CIRCUIT BOARD

(71) Applicant: CANON KABUSHIKI KAISHA, Tokyo (JP)

(72) Inventors: HIROYUKI YAMAGUCHI, Kanagawa (JP); NOBUAKI YAMASHITA, Kanagawa (JP); YOSHITOMO FUJISAWA, Kanagawa (JP)

(21) Appl. No.: 18/642,395

(22) Filed: Apr. 22, 2024

(30) Foreign Application Priority Data
Apr. 28, 2023 (JP) 2023-075163

(51) Int. Cl. H05K 1/02; H01G 4/12; H05K 1/18; H05K 3/30; H05K 3/34

(52) U.S. Cl. CPC H05K 1/0231; H01G 4/12; H05K 1/181; H05K 3/303; H05K 3/3442; H05K 2201/10015; H05K 2201/10515

(57) ABSTRACT

A circuit board includes a wiring board, a first capacitor, a second capacitor, and a semiconductor device. The first capacitor and the second capacitor are stacked to each other on the wiring board. The semiconductor device is mounted on the wiring board. The first capacitor is provided between the second capacitor and the wiring board. A second capacitance of the second capacitor is larger than a first capacitance of the first capacitor.

### BACKGROUND

### Field

This disclosure relates to a circuit board, an electronic device, and a method of manufacturing the circuit board.

### Description of the Related Art

Countermeasures against noise are required in the circuit board.

Japanese Patent Application Laid-Open No. 2017-042040 discloses that a noise suppressing capacitor with a capacitance smaller than a capacitance of the snubber capacitor is provided between the snubber capacitor and the inverter between the positive line and the negative line of the DC power supply line.

In the configuration of Japanese Patent Application Laid-Open No. 2017-042040, the influence of the parasitic inductance component in the wiring between the small-capacitance capacitor and the large-capacitance capacitor is likely to occur.

### SUMMARY

The present disclosure works towards providing an advantageous technology for noise control of the circuit board.

According to an aspect of the present disclosure, a circuit board includes a wiring board, a first capacitor and a second capacitor that are stacked to each other on the wiring board, and a semiconductor device that is mounted on the wiring board, wherein the first capacitor is provided between the second capacitor and the wiring board, and wherein a second capacitance of the second capacitor is larger than a first capacitance of the first capacitor.

Further features of the present disclosure will become apparent from the following description of exemplary embodiments with reference to the attached drawings.

### BRIEF DESCRIPTION OF THE DRAWINGS

FIG. 1 is a perspective view illustrating a circuit board according to a first embodiment.

FIG. 2 is a side view illustrating a circuit board illustrated in FIG. 1.

FIG. 3 is a perspective view illustrating the circuit board according to Comparative Example 1 against the circuit board illustrated in FIG. 1.

FIG. 4 is a perspective view illustrating a circuit board according to Comparative Example 2 against the circuit board illustrated in FIG. 1.

FIG. 5 is a perspective view illustrating a circuit board according to Comparative Example 3 against the circuit board illustrated in FIG. 1.

FIG. 6 is a view illustrating the relationship between the frequency and the power source impedance in the circuit boards of Example 1, Comparative Example 1 and Comparative Example 2.

FIG. 7 is a view illustrating the relationship between the frequency and the power source impedance in the circuit boards of Example 1, Comparative Example 1 and Comparative Example 3.

FIG. 8 is a perspective view illustrating a circuit board according to a second embodiment.

FIG. 9 is a side view illustrating a circuit board according to Comparative Example 4 against Example 2.

FIG. 10 is a diagram illustrating the relationship between the frequency and the power source impedance in the circuit board of Example 2 and Comparative Example 4.

FIG. 11 is a perspective view illustrating a circuit board according to a third embodiment.

FIG. 12 is a side view illustrating a circuit board according to Comparative Example 4 against the circuit board illustrated in FIG. 11.

FIG. 13 is a side view illustrating an arrangement example (1) of a plurality of capacitors in the circuit board according to a fourth embodiment.

FIG. 14 is a side view illustrating an arrangement example (2) of a plurality of capacitors in the circuit board according to the fourth embodiment.

FIG. 15 is a side view illustrating an arrangement example (3) of a plurality of capacitors in a circuit board according to the fourth embodiment.

FIG. 16 is a view for explaining a method of manufacturing a circuit board according to a fifth embodiment.

FIG. 17 is a view for explaining the method of manufacturing the circuit board according to the fifth embodiment.

### DESCRIPTION OF THE EMBODIMENTS

In recent years, the malfunction of semiconductor devices has increased with the increase in circuit operation speed and the decrease in power supply voltage. The cause of the malfunction is the fluctuation of the power supply potential of semiconductor devices due to external noise propagating through the power supply wiring of printed circuit boards and internal noise caused by the operation of semiconductor devices themselves. Manufacturers of semiconductor devices recommend measures to arrange external filters such as ferrite beads for external noise and capacitors with small capacitance near power supply terminals of semiconductor devices for internal noise.

For example, a low-pass filter composed of two capacitors and a ferrite bead can reduce an external noise having a frequency component equal to or greater than a cutoff frequency, thereby avoiding malfunction of the semiconductor device. However, in this method, a parallel resonance between the internal inductance component of the ferrite bead and the capacitance component of the capacitor occurs at a frequency near the cutoff frequency, thereby increasing the power source impedance. This may inversely amplify the external noise and cause a malfunction.

To avoid such parallel resonance, instead of an external filter with an inductance component such as a ferrite bead, a capacitor with a large capacitance is arranged between the power supply device and the ground to suppress the power supply impedance and avoid a malfunction. For example, a small capacitor with a small capacitance is arranged near a semiconductor device to suppress internal noise, and a large-capacitance capacitor is arranged in parallel outside the small capacitor.

When two capacitors with different capacitances are arranged in parallel, one capacitor must have a large capacitance. However, a capacitor with a large capacitance has a larger size and difficult to be arranged in the vicinity of the semiconductor device. In the vicinity of the semiconductor device, many substrate wirings and electrical components are crowded for signal input/output and power supply to other components around the semiconductor device, and there is no space left to place a large-size capacitor therein. The power source impedance can be reduced, but the space is consumed to place the substrate wiring and electrical components near the semiconductor device. As a result, the miniaturization of the printed wiring board is hindered.

It is also possible to use a method in which a large-capacity capacitor is arranged at a position slightly away from the semiconductor device. A capacitor having a small capacitance and a small size is mounted to suppress internal noise in the semiconductor device. However, in this method, the power source impedance increases at the frequency of parallel resonance between the small-capacity and small-size capacitor and the parasitic inductance component of the substrate wiring from the capacitor to the large-capacity capacitor. Thereby, the possibility of malfunction of the semiconductor device in response to external noise increases.

In the following embodiment, for example, a technique for miniaturizing a printed circuit board while reducing the power source impedance is disclosed.

### First Embodiment

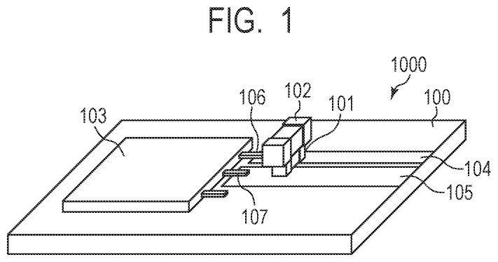

Hereinafter, power source impedance in the circuit board of the first embodiment of the present disclosure will be described with reference to FIGS. 1 to 7. In the following examples, a typical printed wiring board is exemplified as a wiring board used in the circuit board, but it is not essential that the wiring of the wiring board is formed by a printing technique. The wiring board may be a rigid wiring board, but the wiring board may be a flexible wiring board.

FIG. 1 is a perspective view illustrating a circuit board 1000 according to the first embodiment. In FIG. 1, the circuit board 1000 includes a printed wiring board 100, a first capacitor 101, and a second capacitor 102. The first capacitor 101 is arranged on at least one of two main surfaces of the printed wiring board 100. At least one of the two main surfaces of the printed wiring board 100 can be referred to as a mounting surface. The second capacitor 102 is stacked on the first capacitor 101. The second capacitor 102 has a larger capacitance than the first capacitor 101. In this way, the first capacitor 101 and the second capacitor 102 are stacked to each other on the printed wiring board 100.

The circuit board 1000 also includes a semiconductor device 103. The semiconductor device 103 is arranged on the main surface of the printed wiring board 100. The semiconductor device 103 includes a power supply terminal 106 and a ground terminal 107. The power supply terminal 106 is connected to the power supply wiring 104 formed on the main surface of the printed wiring board 100. The ground terminal 107 is connected to the ground wiring 105 formed on the main surface of the printed wiring board 100. A power source is supplied from the power supply device (not illustrated) to the semiconductor device 103 via the power supply wiring 104 and the ground wiring 105. A power supply device that supplies power to the semiconductor device 103 may be a semiconductor device arranged on the printed wiring board 100. The power supply device may be mounted on the same main surface as the first capacitor 101 and the second capacitor 102, or on a different main surface than the first capacitor 101 and the second capacitor 102. The power supply device may be mounted on the same main surface as the semiconductor device 103, or on a different main surface than the semiconductor device 103. The power supply device may be arranged outside the printed wiring board 100. In this embodiment, the power supply wiring 104 and the ground terminal 107 are illustrated as the first power supply wiring and the second power supply wiring of the printed wiring board 100, respectively, but the polarity may be opposite.

As illustrated in FIG. 1, the first capacitor 101 and the second capacitor 102 are arranged in the vicinity of the semiconductor device 103 on the main surface of the printed wiring board 100 and within a predetermined distance from the semiconductor device 103. The predetermined distance range is, for example, within 50 millimeters (mm) from the semiconductor device 103. That is, the first capacitor 101 and the second capacitor 102 can be arranged within 50 mm from the semiconductor device 103. The predetermined distance range is preferably within a range equivalent to the outer size L of the semiconductor device 103 from the semiconductor device 103. More preferably, the predetermined distance range is within a range equivalent to half (L/2) of the outer size L of the semiconductor device 103 from the semiconductor device 103. The outer size L of the semiconductor device 103 is 5-50 mm, typically 10-20 mm. The predetermined distance range is within the range from the semiconductor device 103 to 15-20 mm if the outer size L of the semiconductor device 103 is 15-20 mm. The predetermined distance range is preferably within the range from the semiconductor device 103 to 10 mm, for example. According to the present embodiment, the distance between the first capacitor 101 and the second capacitor 102 can be made as small as possible, but it is preferable that the first capacitor 101 and the second capacitor 102 be closer to the semiconductor device 103. The center of each of the first capacitor 101 and the second capacitor 102 is arranged on a straight line in the stacking direction (In View, Vertical) of the first capacitor 101 and the second capacitor 102.

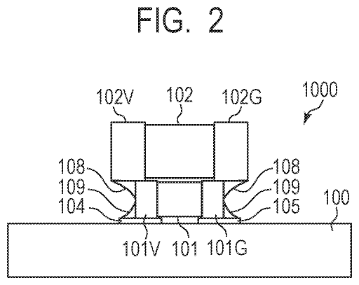

FIG. 2 is a side view of the circuit board 1000 according to the first embodiment viewed from the longitudinal side surfaces of the first capacitor 101 and the second capacitor 102. As illustrated in FIG. 2, the first capacitor 101 includes a power supply terminal 101V and a ground terminal 101G. The power supply wiring 104 is connected to the power supply terminal 101V of the first capacitor 101. The ground wiring 105 is connected to the ground terminal 101G of the first capacitor 101.

The second capacitor 102 has a power supply terminal 102V and a ground terminal 102G. The power supply terminal 101V of the first capacitor 101 faces the power supply terminal 102V of the second capacitor 102. Similarly, the ground terminal 101G of the first capacitor 101 faces the ground terminal 102G of the second capacitor 102.

The first fillet 108 and the second fillet 109 are fillets composed of solder. The first fillet 108 electrically connects the power supply terminal 101V of the first capacitor 101 and the power supply terminal 102V of the second capacitor 102. The first fillet 108 electrically connects the ground terminal 101G of the first capacitor 101 and the ground terminal 102G of the second capacitor 102.

Similarly, the second fillet 109 electrically connects the power supply terminal 101V of the first capacitor 101 to the power supply wiring 104. The second fillet 109 electrically connects the ground terminal 101G of the first capacitor 101 to the ground wiring 105.

In Example 1 of the circuit board 1000 illustrated in FIGS. 1 and 2, a first size (1 mm×0.5 mm) multilayer ceramic capacitor with a capacitance of 0.15 microfarad (μF) was used for the first capacitor 101. A second size (1.6 mm×0.8 mm) multilayer ceramic capacitor with a capacitance of 3.9 μF was used for the second capacitor 102. In this specification, an important “size” of the capacitor is the size of the capacitor in the direction along the mounting surface of the printed wiring board 100. This is because the size of the capacitor in the direction along the mounting surface of the printed wiring board 100 affects the exclusive area of the capacitor in the mounting surface (main surface) of the printed wiring board 100. When the shape of the capacitor in the direction along the mounting surface of the printed wiring board 100 is substantially rectangular, the size in the longitudinal direction is more important out of the size in the longitudinal direction and the size in the short direction. In a capacitor, typically, two terminals are arranged in the longitudinal direction. In addition, the distance between the two terminals of the capacitor is important from the viewpoint of mounting reliability (e.g., short circuit defect). Therefore, typically, the size of the capacitor in the direction in which the two terminals of the first capacitor 101 line up on the mounting surface and the size of the capacitor in the direction in which the two terminals of the second capacitor 102 line up on the mounting surface are important.

Next, Comparative Examples 1-3 against the circuit board 1000 illustrated in FIG. 1 will be described. For the first capacitor 101 and the second capacitor 102 in Comparative Examples 1-3, the same capacitor as in Example 1 was used.

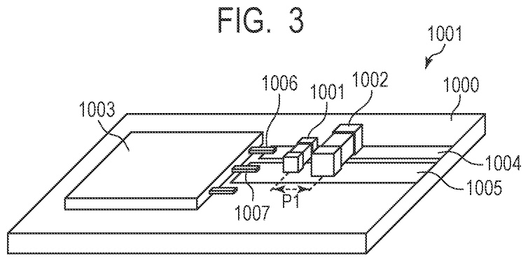

FIG. 3 is a perspective view illustrating a circuit board 1001 of the Comparative Example 1 against the circuit board 1000 illustrated in FIG. 1. The Comparative Example 1 illustrated in FIG. 3 illustrates an example in which a small capacitor with a small capacitance is arranged near the semiconductor device 103 for internal noise suppression, and a capacitor with a large capacitance is arranged in parallel outside the small capacitor.

The circuit board 1001 is provided with a printed wiring board 100, a first capacitor 101, a second capacitor 102, a semiconductor device 103, a power supply wiring 104, a ground wiring 105, a power supply terminal 106, and a ground terminal 107 in the same manner as the circuit board 1000 in the embodiment 1. The power supply terminal 106 is connected to the power supply wiring 104 formed on the main surface of the printed wiring board 100. The ground terminal 107 is connected to the ground wiring 105. The power supply wiring 104 is connected to the power supply terminal of the first capacitor 101. The ground wiring 105 is connected to the ground terminal of the first capacitor 101. Similarly, the power supply wiring 104 is connected to the power supply terminal of the second capacitor 102. The ground wiring 105 is connected to the ground terminal of the second capacitor 102. In FIG. 3, the pitch P1 between the first capacitor 101 and the second capacitor 102 is set to 1.6 mm.

The first capacitor 101 has a smaller capacitance than a capacitance of the second capacitor 102. In the configuration of Comparative Example 1, the second capacitor 102 must have a large capacitance and is difficult to be arranged in the vicinity of the semiconductor device 103. The reason is that a large number of wirings and components for processing signals and power supplies with other components in the vicinity of the semiconductor device 103 are crowded, and there is no space left for a large-sized capacitor.

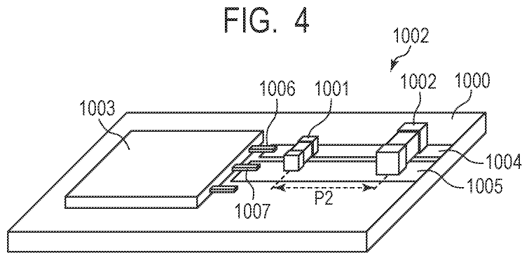

FIG. 4 is a perspective view illustrating a circuit board 1002 according to Comparative Example 2 against the circuit board 1000 illustrated in FIG. 1. In Comparative Example 2 illustrated in FIG. 4, the first capacitor 101 with a large capacitance is arranged slightly apart from the semiconductor device 103. In FIG. 4, the pitch P2 between the first capacitor 101 and the second capacitor 102 is set to 10 mm.

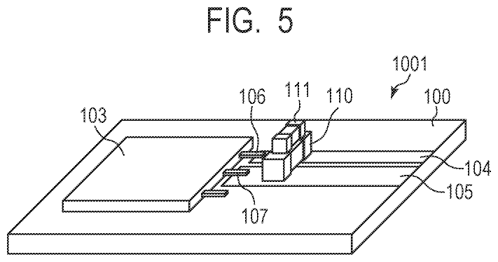

FIG. 5 is a perspective view illustrating a circuit board 1003 according to Comparative Example 3 against the circuit board 1000 illustrated in FIG. 1. The difference between the circuit board 1000 of Example 1 and the circuit board 1003 of Comparative Example 3 is that the first capacitance of the first capacitor 101 in Comparative Example 3 is larger than the second capacitance of the second capacitor 102.

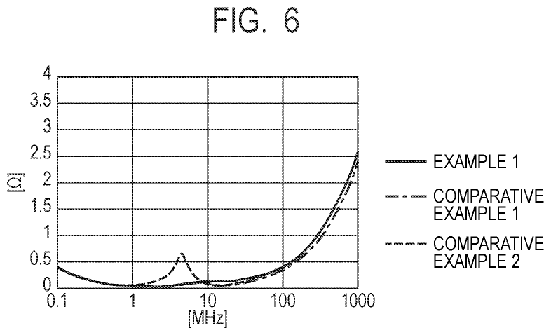

FIG. 6 is a diagram illustrating the relationship between the frequency and the power source impedance in the circuit boards of Example 1, Comparative Example 1, and Comparative Example 2. For the calculation of the power source impedance, ANSYS Electronics Desktop 2020R2 is used.

In the measurement of the power source impedance in Example 1, Comparative Example 1 and Comparative Example 2, the power supply terminal 106 and the ground terminal 107 of the semiconductor device 103 were used as observation points.

Referring to FIG. 6, the power source impedance can be reduced in Comparative Example 1. However, in the configuration of Comparative Example 1, the space of the substrate wiring and component arrangement in the vicinity of the semiconductor device 103 is consumed. Therefore, as a result, it is expected that the miniaturization of the printed wiring board 100 will be hindered.

On the other hand, in Comparative Example 2, the power source impedance increases at the frequency of the parallel resonance of the parasitic inductance component of the substrate wiring between the first capacitor 101 with a small capacitance and a small size mounted for internal noise suppression of the semiconductor device 103 and the second capacitor 102 with a large capacitance. As a result, it is expected that it is difficult to prevent the malfunction of the semiconductor device 103 against the external noise. Further, it can be seen in Example 1 that the increase of the power supply impedance due to the parallel resonance occurring in the frequency band of 5 MHz in Comparative Example 2 does not occur in Comparative Example 1 and Comparative Example 3.

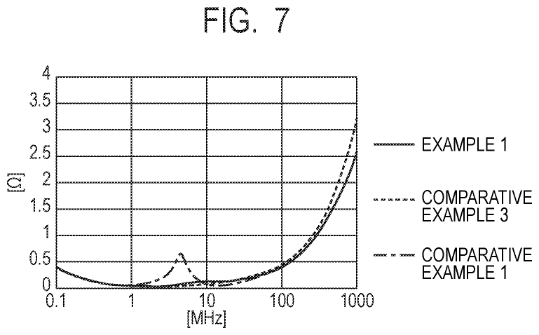

FIG. 7 is a diagram illustrating the relationship between the frequency and the power source impedance in the circuit boards in Example 1, Comparative Example 2 and Comparative Example 3. In the measurement of the power source impedance in Example 1, Comparative Example 2 and Comparative Example 3, the power supply terminal 106 and the ground terminal 107 of the semiconductor device 103 were used as observation points.

Referring to FIG. 7, the increase in the power source impedance due to the parallel resonance occurring in the frequency band of 5 MHz in Comparative Example 2 does not occur in Comparative Example 1 and Comparative Example 3. Further, it can be seen that in the frequency band of 100 MHz or more, the power source impedance decreased in Example 1 compared to Comparative Example 3. The impedance in this band is dominated by the ESL (equivalent series inductance) inside the capacitor and the parasitic inductance of the power source ground wiring.

The smaller the component size, the smaller the ESL, and the impedance can be reduced by placing the capacitor closer to the power source ground terminal of the semiconductor device. Therefore, in the band of 100 MHz or more, the power source impedance can be reduced in Example 1 compared to Comparative Example 3.

In the 1 MHz band and the 10 MHz band, the power source impedance in Example 1 is larger than the power source impedance in Comparative Example 3. However, this is not a practical problem. The reason is that a possibility of malfunction of the semiconductor device 103 can be suppressed if the power source impedance is reduced to a certain extent, and there is no substantial difference even if the power source impedance is reduced excessively.

Further, the exclusive area of the capacitor on the main surface of the printed wiring board 100 can be reduced in the first embodiment compared with Comparative Examples 1-3. The vacant space can be used for other wiring or the printed wiring board 100 can be reduced in size.

As described above, the circuit board 1000 according to the present embodiment can reduce the size of the printed wiring board while reducing the power source impedance.

### Second Embodiment

Hereinafter, a circuit board according to the second embodiment will be described. The circuit board according to the present embodiment differs from the circuit board according to the first embodiment in that the inner electrode surfaces of the capacitors are arranged so as to intersect with the main surface (mounting surface) of the printed wiring board on which the capacitors are mounted.

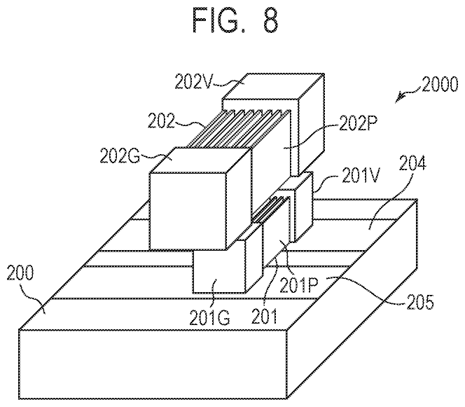

FIG. 8 is a diagram illustrating the circuit board 2000 according to the second embodiment. In FIG. 8, the circuit board 2000 includes a printed wiring board 200, a first capacitor 201 arranged on the main surface of the printed wiring board 200, and a second capacitor 202 stacked on the first capacitor 201.

The power supply terminal of the semiconductor device (not illustrated) is connected to the power supply wiring 204 formed on the main surface of the printed wiring board 200. The ground terminal of the semiconductor device is connected to the ground wiring 205 formed on the main surface of the printed wiring board 200. The power supply wiring 204 is connected to the power supply terminal 201V of the first capacitor 201. The ground wiring 205 is connected to the ground terminal 201G of the first capacitor 201.

The first capacitor 201 and the second capacitor 202 are multilayer ceramic capacitors. The first capacitor 201 has a smaller capacitance than a capacitance of the second capacitor 202. The first capacitor 201 and the second capacitor 202 have a structure to realize a desired capacitance by laminating a plurality of thin film electrodes 201P and 202P inside, respectively.

In the printed wiring board 200 of the second embodiment, the first capacitor 201 and the second capacitor 202 are arranged so that the inner electrode surfaces of the thin film electrodes 201P and 202P are perpendicular to the main surface of the printed wiring board 200. In this way, the inner electrode surfaces of the first capacitor 201 and the second capacitor 202 are arranged so as to intersect each other with respect to the mounting surface of the printed wiring board 200. The inner electrode surface of the first capacitor 201 is arranged along the inner electrode surface of the second capacitor 202.

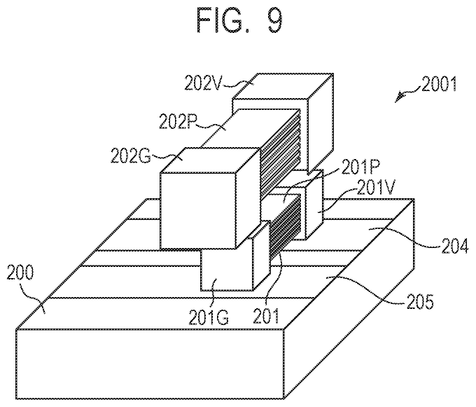

FIG. 9 is a perspective view illustrating the circuit board 2001 according to Comparative Example 4 against the circuit board 2000 illustrated in FIG. 8. In the circuit board 2001 of Comparative Example 4, the surface of the thin film electrode 201P of the first capacitor 201 and the surface of the thin film electrode 202P of the second capacitor 202 are arranged in parallel with the main surface of the printed wiring board 200. As described above, the inner electrode surfaces of the first capacitor 201 and the second capacitor 202 are arranged along the mounting surface of the printed wiring board 200.

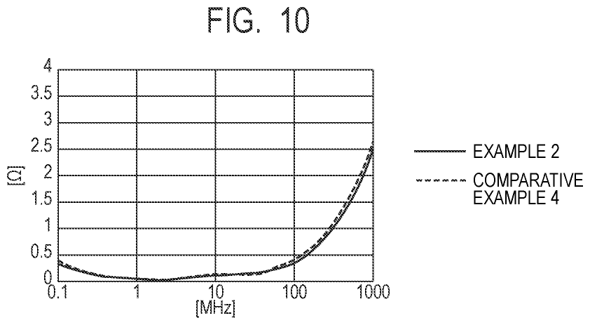

FIG. 10 is a diagram illustrating the relationship between the frequency and the power source impedance in Example 2 using the circuit board 2000 of the present embodiment and Comparative Example 4 using the circuit board 2001. In Example 2 and Comparative Example 4, a first size (1 mm×0.5 mm) multilayer ceramic capacitor with a capacitance of 0.15 μF was used for the first capacitor 201. A second size (1.6 mm×0.8 mm) multilayer ceramic capacitor with a capacitance of 3.9 μF was used for the second capacitor 202.

Referring to FIG. 10, the impedance in Example 2 is generally lower than the impedance in Comparative Example 4 over the entire frequency band. This difference can be attributed to the fact that the high-frequency current tends to be concentrated on the surface and end of the conductor. In Comparative Example 4, compared with Example 2, the edges of the thin film electrode 201P inside the multilayer ceramic capacitor and the edges of the thin film electrode 202P are more frequently located close to the main surface of the printed wiring board 200. Therefore, in Example 2 than in Comparative Example 4, the electromagnetic coupling generated between the thin film electrode 201P, the thin film electrode 202P, and the conductor layer of the terminals (power supply terminal and ground terminal) (not illustrated) inside the printed wiring board 200 becomes stronger, resulting in a low impedance.

As described above, the circuit board 2000 according to this embodiment makes it possible to miniaturize the printed wiring board while reducing the power supply impedance.

### Third Embodiment

Hereinafter, a circuit board according to a third embodiment will be described. The circuit board according to the present embodiment differs from the circuit boards according to the first and second embodiments described above in that the semiconductor device is mounted on a surface (opposite surface) opposite to one main surface of the printed circuit board on which the capacitor is mounted.

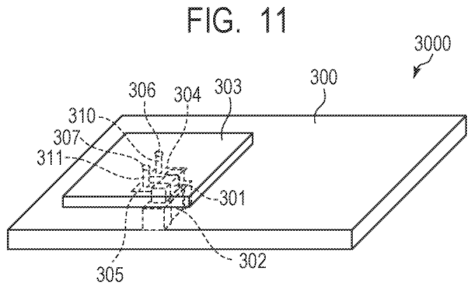

FIG. 11 is a perspective view illustrating the circuit board 3000 according to the third embodiment. In FIG. 11, the circuit board 3000 includes a printed wiring board 300, a first capacitor 301, and a second capacitor 302. The first capacitor 301 is arranged on the main surface of the printed wiring board 300. The second capacitor 302 is stacked on the first capacitor 301.

The semiconductor device 303 is arranged on a surface (second mounting surface) opposite to the surface (first mounting surface) of the printed wiring board 300 on which the first capacitor 301 is mounted. The first capacitor 301 and the second capacitor 302 are arranged at positions overlapping the semiconductor device 303 in a direction perpendicular to the first mounting surface. The semiconductor device 303 has a power supply terminal 306 and a ground terminal 307. The power supply terminal 306 is arranged between the semiconductor device 303 and the printed wiring board 300 and is connected to the power supply wiring 304 formed on the main surface of the printed wiring board 300. Similarly, the ground terminal 307 is arranged between the semiconductor device 303 and the printed wiring board 300 and is connected to the ground wiring 305 formed on the main surface of the printed wiring board 300.

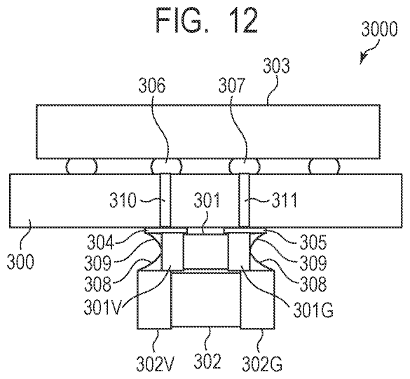

FIG. 12 is a side view of the circuit board 3000 of the third embodiment viewed from the longitudinal side surfaces of the first capacitor 301 and the second capacitor 302. The first capacitor 301 has a power supply terminal 301V and a ground terminal 301G. The second capacitor 302 has a power supply terminal 302V and a ground terminal 302G.

The power supply wiring 304 is connected to the power supply terminal 301V of the first capacitor 301 through a power supply via 310. Similarly, the ground wiring 305 is connected to the ground terminal 301G of the first capacitor 301 through a ground via 311. The first capacitor 301 has a smaller capacitance than a capacitance of the second capacitor 302.

The first fillet 308 and the second fillet 309 are fillets composed of solder. The first fillet 308 connects the power supply terminal 301V of the first capacitor 301 and the power supply terminal 302V of the second capacitor 302. The first fillet 308 connects the ground terminal 301G of the first capacitor 301 and the ground terminal 302G of the second capacitor 302.

Similarly, the second fillet 309 connects the power supply terminal 301V of the first capacitor 301 and the power supply wiring 304. The second fillet 309 connects the ground terminal 301G of the first capacitor 301 and the ground wiring 305.

The power supply wiring 304 is connected to the semiconductor device 303 through the power supply via 310 and the power supply terminal 306. The ground wiring 305 is connected to the semiconductor device 303 through the ground via 311 and the ground terminal 307.

With the above configuration, it is possible to reduce the power source impedance and to miniaturize the printed wiring board even for semiconductor devices such as BGA packages having connection terminals on the reverse side.

### Fourth Embodiment

Hereinafter, a circuit board according to a fourth embodiment will be described. The circuit board according to the present embodiment differs from the circuit board according to the first to third embodiments described above in that the circuit board has a structure in which N (N is a natural number equal to or greater than 3) capacitors are stacked on a printed wiring board.

In the present embodiment, a case in which three capacitors are stacked on the main surface of the printed wiring board in the order of a first capacitor, a second capacitor, and a third capacitor will be described as an example. However, the number of capacitors to be stacked is not limited to three. In addition, there may be various variations in capacitance and size of capacitors.

In the present embodiment, the first capacitor has the smallest component size and capacitance and is located closest to the main surface of the printed circuit board. The second capacitor is a capacitor provided between the first capacitor and the third capacitor. The third capacitor is a capacitor stacked on the second capacitor and arranged farthest from the main surface of the printed wiring board. The capacitance of the third capacitor is equal to or greater than a capacitance of the second capacitor.

In the present embodiment, the second capacitor and the third capacitor satisfy the following conditions (A) and (B).
(A) The capacitance of the third capacitor is equal to or greater than the capacitance of the second capacitor whose distance from the main surface of the printed wiring board is closer than that of the third capacitor. That is, the capacitance of the third capacitor is equal to or greater than the capacitance of the second capacitor constituting the lower layer.
(B) The component size of the third capacitor is equal to or greater than the size of the second capacitor whose distance from the main surface of the printed wiring board 400 is closer than that of the third capacitor. That is, the component size of the third capacitor is equal to or greater than the size of the second capacitor constituting the lower layer.

Even when four or more capacitors are stacked on the main surface of the printed circuit board, two adjacent capacitors shall similarly satisfy the conditions (A) and (B) described above. That is, when N capacitors are stacked, the capacitance of the capacitor constituting the x (x is a natural number equal to or greater than 2 and less than or equal to N.) th layer from the main surface of the printed circuit board is equal to or greater than the capacitance of the capacitor constituting the lower layer, i.e., the (x−1) th layer. The component size of the capacitor constituting the x th layer is equal to or greater than the size of the capacitor constituting the (x−1) th layer.

However, when N capacitors are stacked, the capacitance and component size of the capacitor located at the top layer are larger than the capacitance and component size of the capacitor located at the bottom layer.

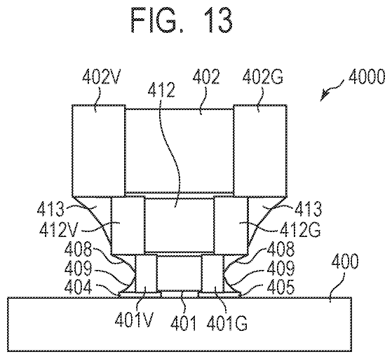

FIGS. 13 to 15 are side views illustrating arrangement examples (1) to (3) of a plurality of capacitors on a circuit board according to the fourth embodiment. FIGS. 13 to 15 illustrate a stacked structure of three capacitors.

FIG. 13 illustrates a case where three capacitors with different sizes are stacked. In FIG. 13, the circuit board 4000 includes a printed wiring board 400, a capacitor 401 (first capacitor), a capacitor 412 (second capacitor) arranged on the capacitor 401, and a capacitor 402 (third capacitor) arranged on the capacitor 412. In order to decrease the component size of the capacitors (capacitor 401, capacitor 412, capacitor 402, in that order), three capacitors are stacked from a position close to the main surface of the printed wiring board 400. The fillet 413 is a fillet composed of solder. The fillet 413 connects the power supply terminal 402V of the capacitor 402 and the power supply terminal 412V of the capacitor 412. The fillet 413 connects the ground terminal 402G of the capacitor 402 and the ground terminal 412G of the capacitor 412.

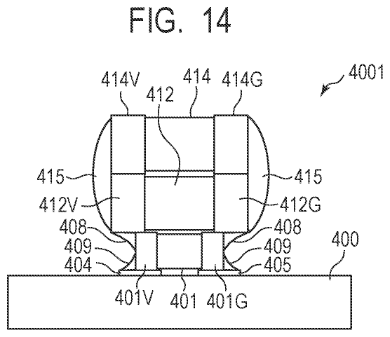

FIG. 14 illustrates a case where one small capacitor and two large capacitors are stacked. In FIG. 14, the circuit board 4001 includes a printed wiring board 400, a capacitor 401 (first capacitor) arranged on the main surface of the printed wiring board 400, a capacitor 412 (second capacitor) arranged on the capacitor 401, and a capacitor 414 (third capacitor) arranged on the capacitor 412. That is, a capacitor (capacitor 401) with the smallest component size is arranged in the bottom layer, and two capacitors (capacitor 412 and capacitor 414) with the same size are stacked on top of the smallest capacitor. The fillet 415 is a fillet composed of solder. The fillet 415 connects the power supply terminal 412V of the capacitor 412 and the power supply terminal 414V of the capacitor 414. The fillet 415 connects the ground terminal 412G of the capacitor 412 and the ground terminal 414G of the capacitor 414.

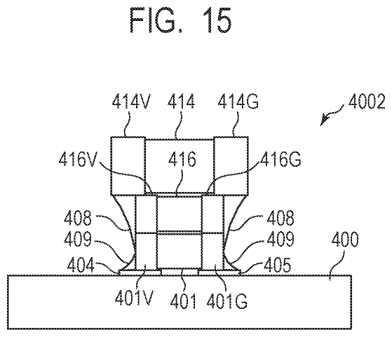

FIG. 15 illustrates a case where two small capacitors and one large capacitor are stacked. In FIG. 15, the circuit board 4002 includes a printed wiring board 400, a capacitor 401 (first capacitor) arranged on the main surface of the printed wiring board 400, a capacitor 416 (second capacitor) arranged on the capacitor 401, and a capacitor 414 (third capacitor) arranged on the capacitor 416. That is, the capacitor 401 and the capacitor 416 are the two capacitors with the smallest component sizes, of which the capacitor 401 is arranged in the bottom layer and the capacitor 416 with the same size is arranged on the capacitor 401. The capacitor 414 with the largest component size is arranged in the top layer.

In FIGS. 13 to 15, variations of the component sizes of the three capacitors have been described, but “component size” may be read as “capacitance”.

As described above, in the circuit board according to the fourth embodiment, a capacitor with a smaller capacitance or a smaller component size is preferentially arranged closer to the main surface of the printed wiring board 400. With such a configuration, the power supply impedance can be reduced and the printed wiring board can be miniaturized even when three or more capacitors are used.

### Fifth Embodiment

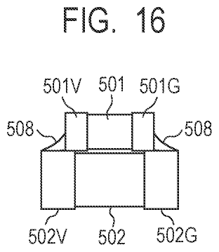

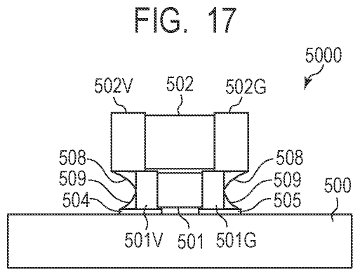

Hereinafter, a circuit board according to a fifth embodiment will be described. FIG. 16 is a drawing for explaining a method of manufacturing the circuit board according to the fifth embodiment. Here, it is assumed that the circuit board is manufactured in the order of FIG. 16 and FIG. 17. In FIG. 16, the first capacitor 501 has a power supply terminal 501V and a ground terminal 501G. The second capacitor 502 has a power supply terminal 502V and a ground terminal 502G.

First, the first capacitor 501 is turned up and the second capacitor 502 is turned down, and the terminals of the first capacitor 501 and the terminals of the second capacitor 502 are connected. Next, the power supply terminal 501V of the first capacitor 501 and the power supply terminal 502V of the second capacitor 502 are connected using the first fillet 508 composed of solder, and the ground terminal 501G of the first capacitor 501 and the ground terminal 502G of the second capacitor 502 are connected.

Next, as illustrated in FIG. 17, the junction parts of the two capacitors manufactured in FIG. 16 are upside down and mounted on the main surface of the printed wiring board 500. With the second capacitor 502 connected to one end surface of the first capacitor 501, the other end surface of the first capacitor 501 is arranged on the main surface of the printed wiring board 500. That is, the first capacitor 501 to which the second capacitor 502 is connected is arranged on the printed wiring board 500 so that the first capacitor 501 is arranged between the second capacitor 502 and the printed wiring board 500.

At this time, the power supply terminal 501V of the first capacitor 501 is connected to the power supply wiring 504 formed on the main surface of the printed wiring board 500, and the ground terminal 501G of the first capacitor 501 is arranged to be connected to the ground wiring 505.

The power supply terminal 501V of the first capacitor 501 and the power supply wiring 504 are connected, and the ground terminal 501G of the first capacitor 501 and the ground wiring 505 are connected by using a second fillet 509 composed of solder.

The melting point of the solder forming the second fillet 509 is preferably lower than the melting point of the solder forming the first fillet 508. Due to the difference in the melting points of the two types of solder, for example, when forming the second fillet 509, it is possible to avoid that the solder of the formed first fillet 508 melts and the second capacitor 502 is detached from the first capacitor 501.

The circuit board according to the present embodiment can be mounted on an electronic device. The electronic device including the circuit board is, for example, a digital camera, but is not limited thereto. For example, the electronic device may be an information device such as a smartphone or a personal computer or a communication device such as a modem or a router. Alternatively, the electronic device may be a business machine such as a printer, a copying machine or a scanner, a medical instrument such as an X-ray image capture device or an endoscope, an industrial machine such as a robot or a semiconductor manufacturing apparatus, or a transportation apparatus such as a vehicle, an aircraft, or a ship. When the circuit board is provided in a limited space within the housing of the circuit board, it is possible to improve the noise resistance and the reliability of electronic devices.

In addition to the circuit board, electronic devices may include electrical apparatus connected to the circuit board. The electrical apparatus connected to the circuit board may be various, such as an electro-optical device such as an image sensor or a display, a storage device such as a memory, an arithmetic device such as a processor, a communication device for performing wireless or wired communication, an electro-mechanical device such as a motor, a power supply device, and the like.

### Modified Embodiment

The present disclosure is not limited to the above-described embodiments but can be modified in various ways. For example, an example in which a partial configuration of one embodiment is added to another embodiment or an example in which a partial configuration of another embodiment is replaced is also an embodiment of the present disclosure.

It should be noted that the above-mentioned embodiments only show examples of embodiment in the implementation of the present disclosure, and the technical scope of the present disclosure should not be interpreted in a limited manner by these embodiments. That is, the present disclosure can be implemented in various forms without departing from its technical philosophy or its main features. For example, multiple embodiments may be combined. In addition, a matter or matters of at least one embodiment can be deleted or replaced. Further, a matter or matters can be newly added to at least one embodiment. The disclosure of the present specification includes not only what is explicitly described herein, but also all that is ascertainable from the present specification and the drawings attached hereto. For example, any combination of each of the described matters is also a part of the disclosure in the present specification. For example, if there are a description “A is equal to or greater than B” and a description “C is equal to or less than D”, the embodiment “A is equal to or greater than B and C is equal to or less than D” is the disclosure in the present specification. In the present specification, “A is equal to or greater than B” (A is an arbitrary element and B is an arbitrary index) means “A is equal to B or A is greater than B”. “C is equal to or less than D (C is an arbitrary element and D is an arbitrary index) means “C is equal to D or C is less than D (under or below D)”. Further, the disclosure in the present specification includes a complement set for each of the individual concepts described in the present specification. That is, if it is described in the present specification that “E is F” (E and F are arbitrary matters), the present specification discloses a case where “E is not F” even though a description for the case where “E is not F” is omitted. This is because, when it is described that “E is F”, it is assumed that the case where “E is not F” is considered.

According to the present disclosure, a technique advantageous for preventing noise in a circuit board is provided.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2023-075163, filed Apr. 28, 2023, which is hereby incorporated by reference herein in its entirety.

What is claimed is:

1. A circuit board comprising:
a wiring board;
a first capacitor and a second capacitor that are stacked to each other on the wiring board; and
a semiconductor device that is mounted on the wiring board,
wherein the first capacitor is provided between the second capacitor and the wiring board, and
wherein a second capacitance of the second capacitor is larger than a first capacitance of the first capacitor.

2. The circuit board according to claim 1, wherein the wiring board has a first power supply wiring connected to a first terminal of the semiconductor device and a second power supply wiring connected to a second terminal of the semiconductor device,
wherein the first capacitor has a first terminal and a second terminal, and
wherein the first terminal of the first capacitor is connected to the first power supply wiring, and the second terminal of the first capacitor is connected to the second power supply wiring.

3. The circuit board according to claim 1, wherein the first capacitor and the second capacitor are arranged from the semiconductor device within 50 millimeters (mm).

4. The circuit board according to claim 1, wherein the semiconductor device is mounted on a mounting surface on which the first capacitor is mounted.

5. The circuit board according to claim 1, wherein the semiconductor device is mounted on a second mounting surface opposite to a first mounting surface on which the first capacitor is mounted on the wiring board.

6. The circuit board according to claim 1, wherein the first capacitor and the second capacitor are arranged at a position overlapping the semiconductor device in a direction perpendicular to a first mounting surface on which the first capacitor is mounted on the wiring board.

7. The circuit board according to claim 1, wherein a center of the first capacitor and a center of the second capacitor are arranged on a straight line in a stacking direction of the first capacitor and the second capacitor.

8. A circuit board comprising:
a wiring board having a mounting surface; and
a first capacitor and a second capacitor that are stacked to each other on the wiring board,
wherein the first capacitor is provided between the second capacitor and the wiring board,
wherein a second capacitance of the second capacitor is larger than a first capacitance of the first capacitor, and
wherein a size of the second capacitor in a direction along the mounting surface of the wiring board is larger than a size of the first capacitor in the direction along the mounting surface of the wiring board.

9. The circuit board according to claim 8, wherein the size of the first capacitor is a size in a direction in which two terminals of the first capacitor line up on the mounting surface, and the size of the second capacitor is a size in a direction in which two terminals of the second capacitor line up on the mounting surface.

10. The circuit board according to claim 8,
wherein the first capacitor has a first terminal and a second terminal,
wherein the second capacitor has a first terminal and a second terminal, and
wherein the first terminal of the first capacitor is connected to the first terminal of the second capacitor and the second terminal of the first capacitor is connected to the second terminal of the second capacitor.

11. The circuit board according to claim 10, wherein the first terminal of the first capacitor is connected to a first power supply wiring of the wiring board, and the second terminal of the first capacitor is connected to a second power supply wiring of the wiring board.

12. The circuit board according to claim 8, wherein the first capacitor and the second capacitor are multilayer ceramic capacitors,
wherein each of inner electrode surfaces of the first capacitor and the second capacitor is respectively arranged to intersect with the mounting surface of the wiring board.

13. The circuit board according to claim 12, wherein the inner electrode surface of the first capacitor is arranged along the inner electrode surface of the second capacitor.

14. The circuit board according to claim 8, wherein the first capacitor and the second capacitor are multilayer ceramic capacitors,
wherein each of inner electrode surfaces of the first capacitor and the second capacitor is arranged along the mounting surface of the wiring board.

15. The circuit board according to claim 8, wherein the first capacitor is electrically connected to the second capacitor via a first solder,
wherein a melting point of the first solder is higher than a melting point of a second solder which electrically connects the first capacitor to wirings of the wiring board.

16. The circuit board according to claim 8, further comprising a third capacitor,
wherein the second capacitor is provided between the first capacitor and the third capacitor.

17. The circuit board according to claim 16, wherein a third capacitance of the third capacitor is equal to or greater than the second capacitance of the second capacitor.

18. The circuit board according to claim 16, wherein a size of the third capacitor is equal to or greater than the size of the second capacitor.

19. An electronic device comprising:
the circuit board according to claim 1; and
an electrical apparatus that is connected to the circuit board.

20. A method of manufacturing a circuit board, the method comprising:
stacking a first capacitor having a first capacitance and a second capacitor having a second capacitance, that is smaller than the first capacitance, to each other on a wiring board;
electrically connecting the stacked first and the second capacitors using a first solder;
arranging the first capacitor to which the second capacitor is connected on the wiring board so that the first capacitor is arranged between the second capacitor and the wiring board; and
electrically connecting the first capacitor and the wiring board using a second solder.

21. The method according to claim 20, wherein a melting point of the first solder is higher than a melting point of the second solder.

22. The method according to claim 20, wherein a third capacitor is stacked on the second capacitor so that the second capacitor is arranged between the first capacitor and the third capacitor.

23. The method according to claim 22, wherein a third capacitance of the third capacitor is equal to or greater than the second capacitance of the second capacitor.
